(19) United States
(12) Patent Application Publication
(10) Pub. No.: US 2009/0085220 A1
(43) Pub. Date: Apr. 2, 2009

(54) SEMICONDUCTOR COMPONENT AND METHOD OF MANUFACTURING

(75) Inventors: Dirk Bernhardt, Dresden (DE); Christine Hinz, Dresden (DE); Kimyung Yoon, Dresden (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/863,883

(22) Filed: Sep. 28, 2007

(51) Int. Cl. H01L 23/52; H01L 21/00

(52) U.S. Cl. 257/777; 438/109; 257/E23.141

(57) ABSTRACT

A semiconductor component and a method of manufacturing is disclosed. One embodiment provides a semiconductor chip with a chip pad and a support pad and a substrate with a substrate pad. The support pad is connected by wire bonding to the chip pad and the support pad.

### BACKGROUND

One or more embodiments provide a semiconductor component and a method of manufacturing.

Semiconductor components are used in electronic systems and usually include one or more semiconductor chips (also called integrated circuits) in one common package.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 to FIG. 5 illustrate schematic cross sections of a semiconductor component with one or more semiconductor chips according to different embodiments.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

A semiconductor component includes a dielectric substrate 10 with substrate pads 11, 22 on both sides of the substrate and through contacts 21 to connect the substrate pads from one side to the other. Solder balls 23 are attached to substrate pads 22 at one side for connection to the next level electronic system.

Instead of solder balls the substrate pads of the semiconductor component may be contacted by contact springs.

A semiconductor chip 12 is attached to the dielectric substrate 10 and includes metal contact areas on the chip called chip pads 13. The chip pads may be located in a central area of the chip surface or in areas near the edge of the chip surface and are connected with the substrate pads 11 e.g., by wire bonding. For chip pads in a central area long bond wires are needed. Long bond wires from central chip pads to substrate pads are subject to cause shorts or damages at the edge of the semiconductor chip.

For prevention of such problems at least one redistribution layer (RDL) may be used to extend the bond pads from the center area to an area near the edge of the chip surface.

For high frequency RDL signals a dielectric layer with a thickness between 5-20 micron is needed, which is thick enough for decoupling between RDL and the underlying signal paths of semiconductor chip. This thick dielectric layer causes chip warpage for semiconductor chips which are thinner than 150 micron.

This invention provides for the introduction of support pads 15. The support pads are contact areas at the edge areas on the dielectric layer 14 of the semiconductor chip and have no electrical connection neither to the semiconductor chip 12 nor to the substrate 10 before wire bonding. A first wire bond connection will be made from the chip pads 13 to the support pads 15, a second wire bond connection will be made from the support pads 15 to the substrate pads 11.

One benefit is to reduce the signal coupling by replacing the redistribution lines, another benefit is to prevent chip warpage caused by thick dielectric layer below the redistribution lines used for signal coupling reduction.

In case of long and direct bond wires from chip pads 13 to substrate pads 11 will be used instead of redistribution lines, one benefit is to fix the wire bond connection near the chip edges to prevent shorts or damage of the wire bond connections.

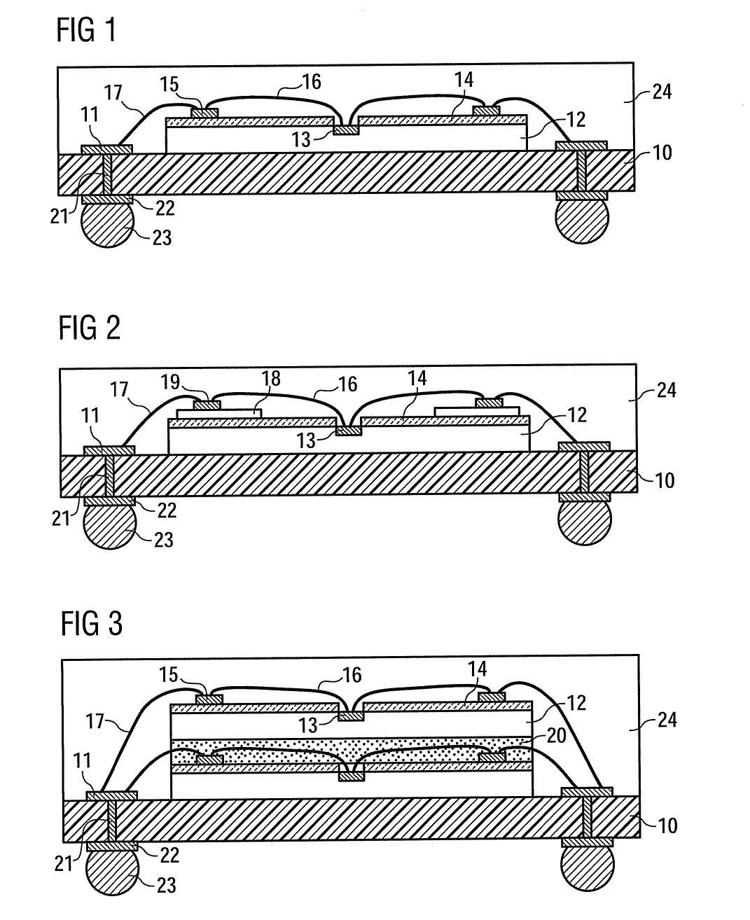

According to one embodiment illustrated in FIG. 1 support pads 15 can be formed by a first metal deposition like chemical or physical vapor deposition directly on the dielectric layer 14 (also called passivation layer) of the semiconductor chip. This metal layer is called seed layer.

In one embodiment the metal layer can be structured by lithography and metal etch after first metal deposition. If the structured metal layer is not thick enough for support pads, the thickness can be enhanced e.g., by metal plating.

In another embodiment a photo resist will be deposited on the seed layer and will be structured by lithography. Then metal layer the seed layer structures not covered by photo resist will be enhanced by metal plating. After that the photo resist structures and the underlying seed layer portions will be removed by metal etch.

Support pads 15 have a minimal size of 50×50 micron (second bond on top of first bond) or 50×100 micron (second bond aside of first bond) and a thickness between 1 and 10 micron. There will be first wire bond connection from chip pads 13 to support pads 15 and second wire bond connection from support pads 15 to substrate pads 11.

According to another embodiment illustrated in FIG. 2 the support pads 15 can be formed on a dielectric material 18 separate from manufacturing process of semiconductor chip 12. Size and thickness of the support pads on the dielectric material are similar to the support pads directly formed on the semiconductor chip 12.

There can be one or more support pads 15 on one piece of dielectric material 18.

In most cases the dielectric material will extend beyond the lateral dimensions of the support pad. In case of one support pad per dielectric material support pad and dielectric material can have equal dimensions, that means the dielectric material is fully covered by the support pad 15.

The dielectric material 18 can be formed like a tape in standard dimensions with support pads as an array in one or more rows and the tape is to be cut to the actual chip size before attaching it to the chip. Alternatively the dielectric material can be formed like a label with dimensions according to special chip type and size and a chip-specific array of support pads.

The dielectric material 18 may include an adhesive on the bottom side for attaching the dielectric material to the chip surface. Alternatively the adhesive can be dispensed on the chip surface in front of attaching the dielectric material to the semiconductor chip 12.

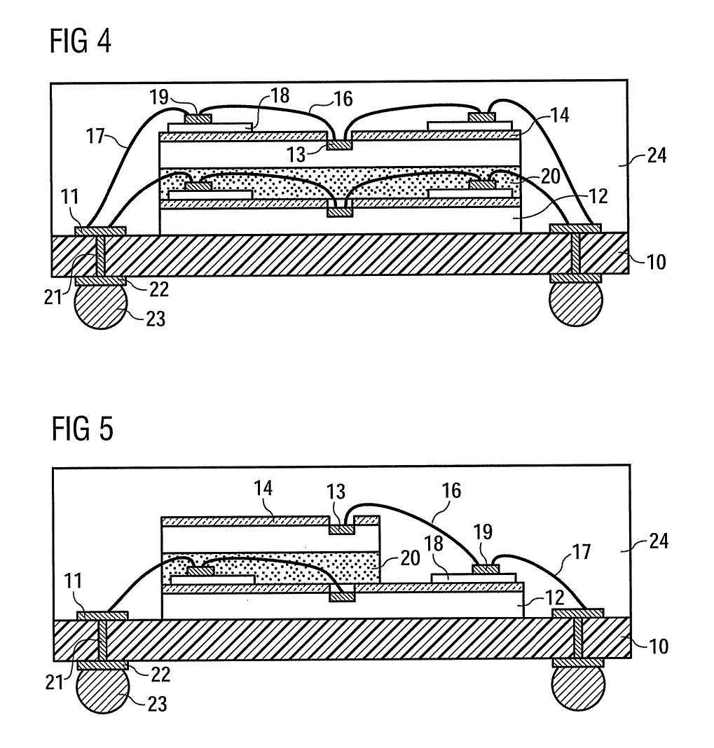

FIG. 3 and FIG. 4 illustrate the embodiments of the invention in connection with stacked semiconductor chips 12. A chip stack includes two or more semiconductor chips of same or different chip type and size. FIG. 5 illustrates an example for different chip size.

The interposer layer 20 can be formed by film on wire material which will be first attached to the bottom side of the upper chip. Then the bottom chip with the interposer layer will be attached to the lower chip surface with its wire bond connections. Because the film on wire material is soft, the wire bond connections will not be damaged by the interposer layer. After die attach of the upper chip the film on wire material can be hardened e.g., by thermal treatment or by UV light.

In one embodiment, a wet adhesive can be dispensed on the lower chip with the wire bond connections before attaching the upper chip. The wet adhesive includes a resin and may include filler spheres for a defined distance between the lower and the upper chip.

The wet adhesive can also be hardened by thermal treatment or by UV light.

The support pad may include any metal. Preferably the body of the support pad includes Copper (Cu) or Aluminum (Al) metal. To prevent the oxidation of the Cu or Al metal surface the support pad may be coated by an organic surface protection (OSP) layer.

Cu or Al metal support pads can be bonded preferably by Cu or Al metal wire bonding, even if the support pads are coated with OSP layer. For Gold (Au) metal wire bonding the Cu metal support pad is preferably coated with Nickel (Ni) metal layer and then with Gold (Au) metal layer.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor component comprising:
a first semiconductor chip with an active side and a bottom side, wherein the active side comprises a first chip pad, a dielectric layer and a first support pad;
a dielectric substrate with a first and a second side and a first substrate pad, wherein the bottom side of the first chip and the first substrate pad are arranged on the first side; and
a first wire bond connection between the first chip pad and the first support pad and a second wire bond connection between the first support pad and the first substrate pad.

2. The semiconductor component of claim 1, comprising wherein the first support pad is arranged on the dielectric layer.

3. The semiconductor component of claim 1, further comprising:
a dielectric material with a top and a bottom side, wherein the first support pad is arranged on the top side of the dielectric material and the bottom side of the dielectric material is attached on the dielectric layer of the first semiconductor chip.

4. The semiconductor component of claim 3, further comprising:
an adhesive on the bottom side of the dielectric material.

5. The semiconductor component of claim 3, further comprising:
an adhesive partially covering the dielectric layer of the semiconductor chip.

6. The semiconductor component of claim 3, comprising wherein a plurality of support pads are arranged on the dielectric material.

7. The semiconductor component of claim 3, comprising wherein the support pad covers almost the of the top side of the dielectric material.

8. The semiconductor component of claim 1, comprising:
a plurality of the chip pads;
a plurality of the support pads;
a plurality of the substrate pads; and
a plurality of the first and second wire bond connections.

9. The semiconductor component of claim 1, wherein the support pad comprises at least one of the metals Copper or Aluminum or Gold.

10. The semiconductor component of claim 1, wherein the surface of support pad comprises an organic surface protection layer.

11. The semiconductor component comprising:
a second semiconductor chip with an active side and a bottom side, wherein the active side comprises a first chip pad, a dielectric layer and a first support pad, wherein the bottom side comprises an dielectric interposer and the second semiconductor chip is arranged on the first semiconductor chip forming a chip stack; and
a first wire bond connection between the first chip pad of the second chip and the first support pad on the second chip and a second wire bond connection between the first support pad of the second chip and the first substrate pad.

12. The semiconductor component of claim 11, wherein the dielectric interposer comprises a film on wire material.

13. The semiconductor component of claim 11, wherein the dielectric interposer comprises a wet adhesive material.

14. The semiconductor component of claim 13, wherein the wet adhesive material comprises filler spheres of similar size.

15. A method of manufacturing a semiconductor component comprising
providing a first semiconductor chip with an active side and a bottom side, wherein the active side comprises a first chip pad, a dielectric layer and a first support pad near the edge of the semiconductor chip;
providing a dielectric substrate with a first and a second side and a first substrate pad, wherein the bottom side of the first chip and the first substrate pad are arranged on the first side of the of the dielectric substrate; and
making a first wire bond connection between the first chip pad and the first support pad and making a second wire bond connection between the first support pad and the first substrate pad.

16. The method of claim 15, wherein provision of the first support pad comprises:
depositing a first metal layer on the dielectric layer of the semiconductor ship;
depositing a photo resist on the first metal layer;
structuring the photo resist by lithography;
depositing a second metal layer on the structured seed layer portions by metal plating process; and
removing the photo resist structures and the seed layer portions below the photo resist by etch process.

17. The method of claim 15, wherein the provision of the first support pad comprises:
providing a dielectric material with a top and a bottom side, wherein the first support pad is arranged on the top side, wherein the bottom side of the dielectric material comprises an adhesive; and
attaching the dielectric material on the dielectric layer of the first semiconductor chip.

18. The method of claim 15, wherein the provision of the first support pad comprises:
providing a dielectric material with a top and a bottom side, wherein the first support pad is arranged on the top side;
providing an adhesive on the dielectric layer of the semiconductor chip; and
arranging the dielectric material on the dielectric layer of the first semiconductor chip.

19. The method of claim 15, comprising:
providing a plurality of the chip pads;
providing a plurality of the support pads;
providing a plurality of the substrate pads; and
making a plurality of the first and second wire bond connections.

20. The method of claim 15, further comprising:
providing a second semiconductor chip with an active side and a bottom side, wherein the active side comprises a first chip pad, a dielectric layer and a first support pad, wherein the bottom side comprises an dielectric interposer;
arranging the bottom side of the second semiconductor chip with the dielectric interposer on the active side of the first semiconductor chip comprising a first and a second wire bond connection;
hardening the dielectric interposer; and
making a first wire bond connection between the first chip pad of the second semiconductor chip and the first support pad on the second semiconductor chip and a second wire bond connection between the first support pad of the second semiconductor chip and the first substrate pad.

21. The method of claim 15, further comprising:
providing a second semiconductor chip with an active side and a bottom side, wherein the active side comprises a first chip pad, a dielectric layer and a first support pad;
providing a wet adhesive on the active side of the first semiconductor chip comprising a first and a second wire bond connection;
arranging the bottom side of the second semiconductor chip on the first semiconductor chip;
hardening the wet adhesive; and
making a first wire bond connection between the first chip pad of the second semiconductor chip and the first support pad on the second semiconductor chip and a second wire bond connection between the first support pad of the second semiconductor chip and the first substrate pad.

22. The method of claim 15, wherein the wet adhesive comprises filler spheres with similar diameter size.
